(19) United States
(12) Patent Application Publication
(10) Pub. No.: US 2013/0176553 A1
(43) Pub. Date: Jul. 11, 2013

(54) METHOD AND APPARATUS FOR NON-DESTRUCTIVE TESTING OF A SEED

(71) Applicant: PIONEER HI-BRED INTERNATIONAL, INC., Johnston, IA (US)

(72) Inventors: Jason Cope, Ankeny, IA (US); David Kurth, Grimes, IA (US)

(73) Assignee: PIONEER HI-BRED INTERNATIONAL, INC., Johnston, IA (US)

(21) Appl. No.: 13/682,010

(22) Filed: Nov. 20, 2012

Related U.S. Application Data
(60) Provisional application No. 61/584,493, filed on Jan. 9, 2012.

(51) Int. Cl. G01J 3/00; G01N 1/04; G01B 11/00; G01N 23/04; G01N 21/31; G01R 33/44; G01N 3/40; B01L 3/00; G01J 3/46

(52) U.S. Cl. CPC G01J 3/00; B01L 3/50; G01N 1/04; G01B 11/00; G01J 3/46; G01N 21/314; G01R 33/44; G01N 3/40; G01N 23/04
USPC 356/51; 73/864.91; 73/864.41; 356/601; 356/402; 324/307; 73/78; 378/62

(57) ABSTRACT

The present invention provides a method and apparatus for non-destructive testing of a seed. In various embodiments, the method may comprise vibrating the seed to orient the seed on an axis, identifying a location of a known feature of the seed, determining a sample location on the seed based on the location of the known feature, and performing a non-destructive testing procedure on the seed proximate the sample location. In one embodiment, the method may comprise removing a sample portion of the seed from the sample location without damaging the embryo of the seed. Accordingly, the viability of the seed may be maintained while allowing for subsequent testing on the sample portion of the seed.

### CROSS-REFERENCE TO RELATED APPLICATIONS

The present application claims priority from U.S. Provisional Application No. 61/584,493, filed Jan. 9, 2012, which is hereby incorporated herein in its entirety by reference.

### FIELD OF THE INVENTION

The present invention relates generally to a method and apparatus for non-destructive testing of a seed, which, in some embodiments, may include removing a sample portion of a seed.

### BACKGROUND OF THE INVENTION

It is conventional practice in plant breeding or plant advancement experiments to grow plants from seeds of known parentage. The seeds are planted in experimental plots, growth chambers, greenhouses, or other growing conditions in which they are either cross pollinated with other plants of known parentage or self pollinated. The resulting seeds are the offspring of the two parent plants or the self pollinated plant, and are harvested, processed and planted to continue the plant breeding cycle. Specific laboratory or field-based tests may be performed on the plants, plant tissues, seed or seed tissues, in order to aid in the breeding or advancement selection process.

Generations of plants based on known crosses or self pollinations are planted and then tested, such as through trait purity tests, to see if these lines or varieties are moving toward characteristics that are desirable in the marketplace. Examples of desirable traits include, but are not limited to, increased yield, increased homozygosity, improved or newly conferred resistance and/or tolerance to specific herbicides and/or pests and pathogens, increased oil content, altered starch content, nutraceutical composition, drought tolerance, and specific morphological based trait enhancements.

In order to test the genetic composition of the seeds, samples of the individual seeds themselves, or of the plants that develop from the seeds, are gathered. However, when the seeds are going to be planted for research purposes, it is important to retain the viability potential of the seed for when it is planted. Conversely, a useful amount of tissue from the seed must also be obtained in order to conduct certain experimental procedures, such as those described above.

Accordingly, prior art methods of non-destructive sampling of seeds have typically relied heavily on manual procedures. For example, one prior art procedure for sampling seeds involves a person grasping an individual seed and cutting off a section of the seed using clippers. In this regard, the user must identify the location of the embryo of the seed so as to avoid damage to the embryo, which could destroy the viability of the seed. Further, the consistency of the sample size was determined by the skill of the person removing the sample from the seed. Accordingly, this prior art method of non-destructive sampling involved large amounts of skilled labor and significant amounts of time due to the requirement that the person avoid damaging the embryo. Similar problems exist for manual hand chipping, drilling, sanding, milling, etc.

The above-mentioned methods of obtaining seed samples from seeds and thereafter transferring the samples to testing apparatuses is extremely time consuming and may involve numerous manual processes. In addition, it is difficult to obtain seed samples having repeatable sample sizes. As a result, there is a need for an improved system and method for obtaining tissue samples, and other forms of non-destructive testing procedures from one or more seeds. In various embodiments, the system and method should provide an efficient manner of gathering seed samples for further processing, such as Deoxyribonucleic acid (“DNA”) and protein purification and extraction, and it should also provide normalized seed particle sample sizes.

### BRIEF SUMMARY OF VARIOUS EMBODIMENTS

In one embodiment a method of non-destructive sampling of a seed is provided. The method may comprise vibrating the seed to orient the seed on an axis, identifying a location of a known feature of the seed, determining a sample location on the seed based on the location of the known feature, and performing a non-destructive testing procedure on the seed proximate the sample location.

In a further embodiment an additional method of non-destructive sampling of a seed is provided. The method may comprise orienting the seed to a desired orientation, identifying a location of a known feature of the seed using machine vision, determining a sample location on the seed based on the location of the known feature, and performing a non-destructive testing procedure on the seed proximate the sample location.

In an additional embodiment an apparatus configured to remove a sample portion of a seed is provided. The apparatus may comprise a vibratory device configured to vibrate the seed and orient the seed on an axis, a camera configured to identify a location of a known feature of the seed, and a testing device configured to perform a non-destructive testing procedure on the seed.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates an apparatus configured to remove a sample portion of a seed according to an embodiment of the invention;

FIG. 2 illustrates a vibratory device which comprises a portion of the apparatus of FIG. 1 according to an embodiment of the invention;

FIG. 3 illustrates a soybean which may be non-destructively sampled using the apparatus of FIG. 1 according to an embodiment of the invention;

FIG. 4 illustrates a machine vision device which comprises a portion of the apparatus of FIG. 1 according to an embodiment of the invention;

FIG. 5 illustrates cutting and depositing operations according to an example embodiment of the invention using the apparatus of FIG. 1;

FIG. 6 illustrates a method of non-destructive sampling of a seed comprising vibrating a seed according to an embodiment of the invention; and

FIG. 7 illustrates a method of non-destructive sampling of a seed comprising identifying a location of a known feature of a seed using machine vision according to an embodiment of the invention.

### DETAILED DESCRIPTION

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

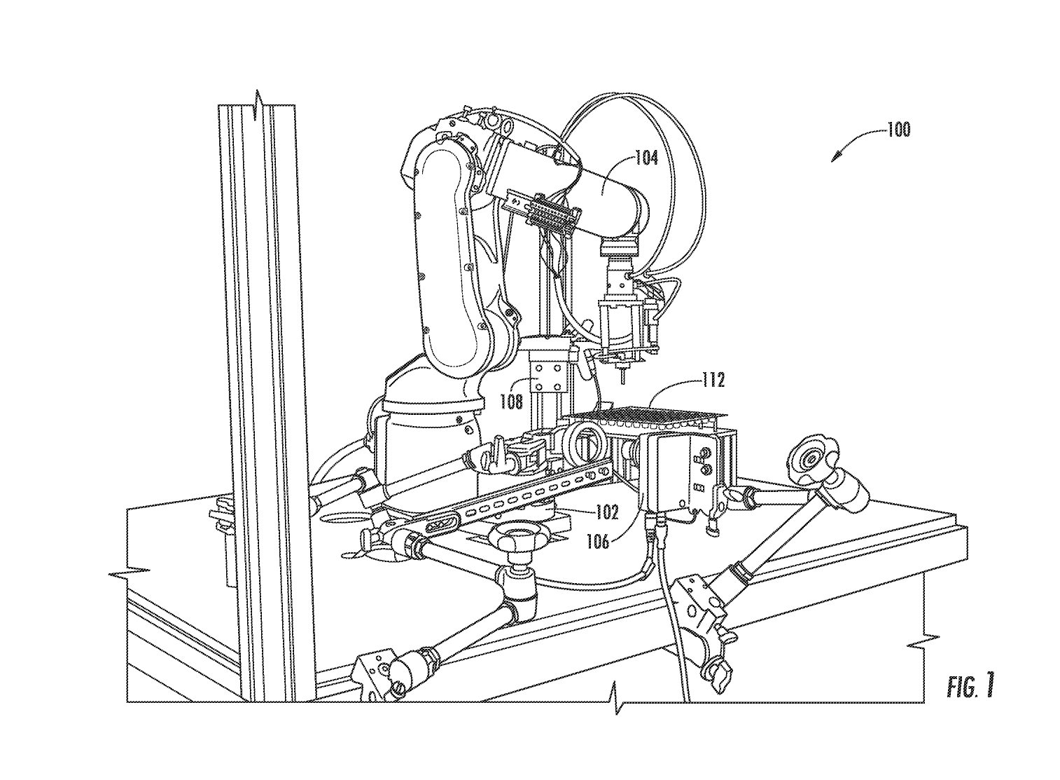

As will be described below, the present invention is generally directed to methods and apparatuses for non-destructive testing of a seed. In one embodiment, the non-destructive testing of the seed comprises removing a sample portion of the seed. In this regard, FIG. 1 illustrates an apparatus 100 which is configured to remove a sample portion of a seed. The apparatus 100 may include a vibratory device 102, which is configured to vibrate a seed and orient the seed on an axis, as will be described below. The apparatus 100 may further include a transport mechanism, which is herein illustrated as a robotic arm 104. The robotic arm 104 may transport seeds between various portions of the apparatus 100 such that various operations may be conducted on the seed. For example, the robotic arm 104 may transfer a seed from the vibratory device 102 to a machine vision device 106. Machine vision, as used herein, refers to apparatuses and methods which use electronic sensory equipment to electronically identify shapes, colors, patterns, orientation, and/or other characteristics of objects. In this regard, the machine vision device 106 will generally be described herein as being camera-based for purposes of brevity. However, the machine vision device 106 may in some embodiments comprise x-ray equipment, magnetic resonance imaging (MRI) equipment; laser three-dimensional (“3-D”) scanners, and various other equipment configured to identify shapes, patterns, orientation, colors, and or other characteristics of objects. Accordingly, the machine vision device 106 may be used to identify a location of a known feature of a seed and/or perform other functions as will be described below.

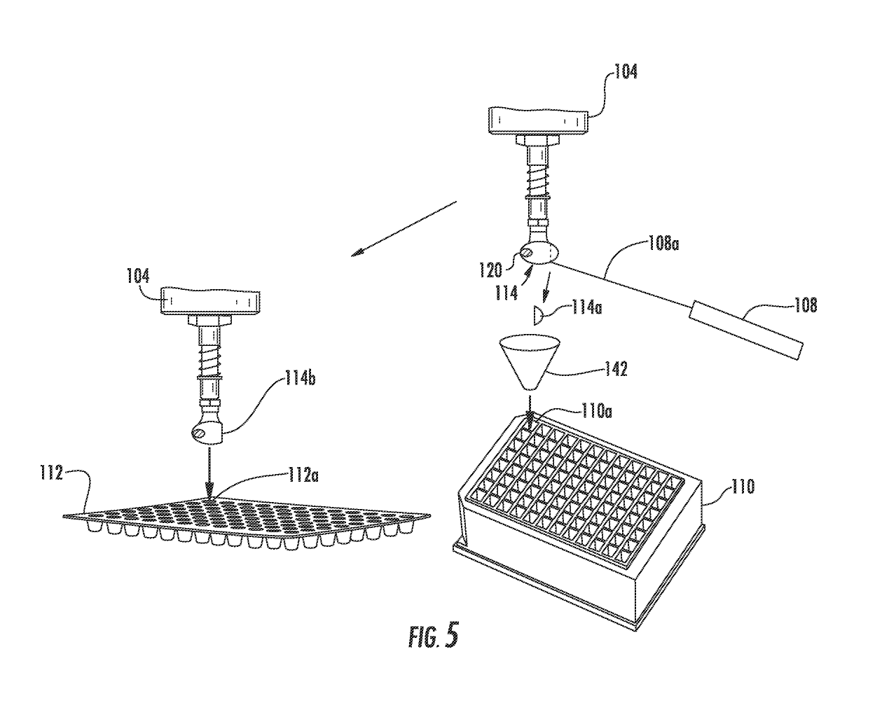

The apparatus 100 may further comprise a cutting device which is configured to cut a seed. As will be described below, the cutting device may comprise a laser 108 in some embodiments. However, in other embodiments the cutting device may additionally or alternatively comprise various other devices which may be used to cut a seed, or take other non-destructive measurements, including but not limited to, NIR, IR, NMR, X-Ray, Hyperspectral, UV and RGB imaging. For example, in some embodiments the cutting device may comprise a blade, scissors, clippers, or other devices configured to cut through a seed. By cutting the seed, a sample portion of the seed may by placed in a first container 110 (see FIG. 5), and a remaining portion of the seed may be placed in a second container 112.

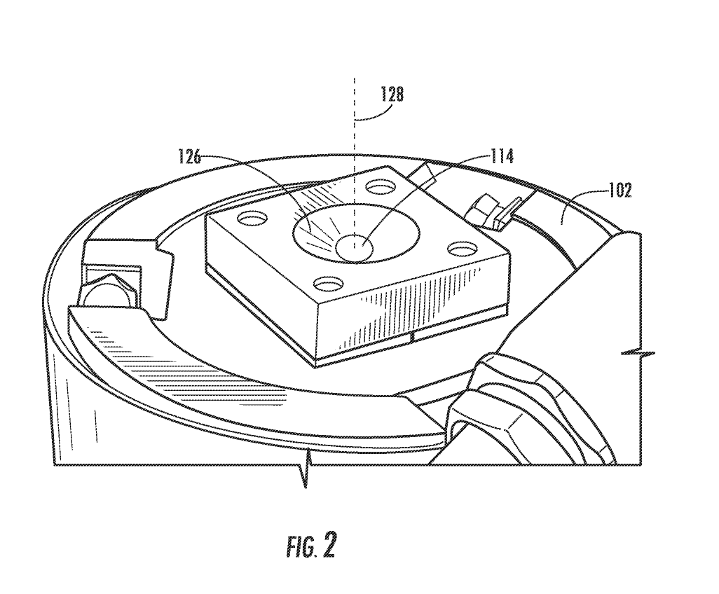

Turning now to FIG. 2, an enlarged view of the vibratory device 102 is illustrated. As described above, the vibratory device 102 is configured to vibrate a seed. The seed in the illustrated embodiment is a soybean seed 114. Soybean seeds generally comprise certain characteristics that will be described herein. However, it should be understood that variances in the genetic composition of soybean seeds, and the differences in various types of soybean seeds may result in some of the description herein differing from some soybean seeds.

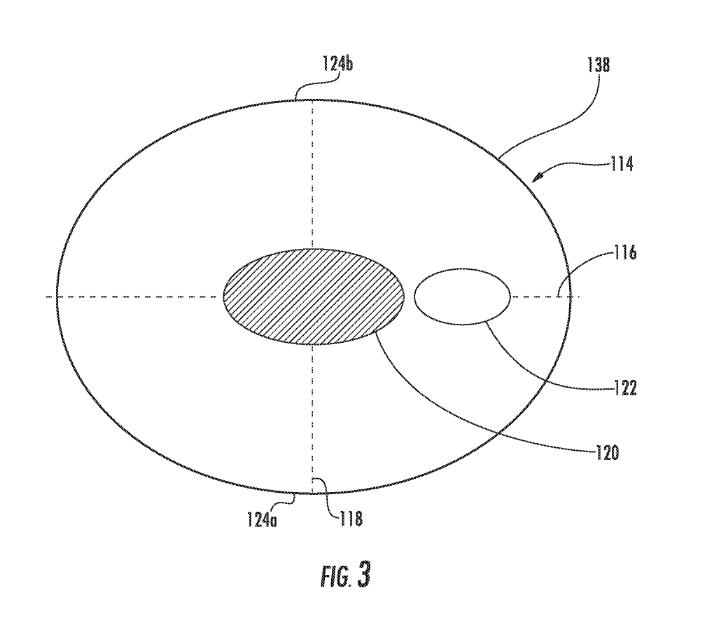

As illustrated, the soybean seed 114 comprises a shape which is generally ovular as viewed from the perspective in FIG. 3. In this regard, the soybean seed 114 has a length on a major axis 116 which is generally greater than a length on a minor axis 118. The soybean seed 114 comprises a hilum 120, which is an externally visible “scar” on the soybean seed, indicating the point of attachment to the funiculus of a soybean plant. The embryo 122 of the soybean seed 114 is within the soybean seed adjacent to the hilum 120, and thus may or may not be externally visible.

Returning to FIG. 2, the soybean seed 114 may be singulated by a singulator and placed in the vibratory device 102. For example, a singulator as disclosed in U.S. patent application Ser. No. 11/939,402 filed on Nov. 13, 2007, which is incorporated herein by reference, may be used in some embodiments. In other embodiments multiple soybean seeds may be inserted into the vibratory device 102, for example when the vibratory device comprises multiple compartments for soybean seeds. By vibrating the soybean seed 114 using the vibratory device 102, the soybean seed may tend to orient itself such that the hilum 120 and the major axis 116 lie generally horizontally. Thus, in this configuration the soybean seed 114 is oriented on the minor axis 118, such that the minor axis is positioned substantially vertically. This occurs because one of the generally flat sections 124a, 124b of the soybean seed 114 will tend to face downwardly due to the force of gravity. Orientation of the soybean seed 114 within the vibratory device 102 may further be assisted by a sloped surface 126. The sloped surface 126 may be configured to center the soybean seed 114 with respect to the sloped surface 126 such that the minor axis 118 of the soybean seed is coaxial with a desired axis 128, which extends substantially vertically from the vibratory device 102.

Note that some embodiments of the apparatus 100 and methods disclosed herein may not include the vibratory device 102. In this regard, while the vibratory device 102 is believed to assist in aligning the minor axis 118 of the soybean seed 114 with the desired axis 128, soybean seeds may tend to naturally orient themselves such that the minor axis is aligned vertically, due to soybean seeds having the flat sections 124a, 124b. Thus, some embodiments may involve placing the soybean seed 114 onto a flat surface or the sloped surface 126 without vibrating the soybean seed.

However, it should also be noted that the methods and apparatuses disclosed herein may be used to conduct operations on various other types of seeds and objects. In this regard, the vibratory device 102 may additionally or alternatively be used to orient other seeds and objects, for example seeds and other objects which are not perfectly spherical or which are not uniformly weighted. Thereby the vibratory device 102 may orient seeds or other objects in a manner similar to that described above with respect to the soybean seed 114. For example, non-spherical seeds or other objects may tend to orient themselves such that they define a minimum height extending vertically. With respect to seeds and objects which are not weighted evenly, the center of mass may be displaced such that it tends to orient downwardly. Accordingly, although the embodiments discussed herein generally refer to soybean seeds, this is for example purposes.

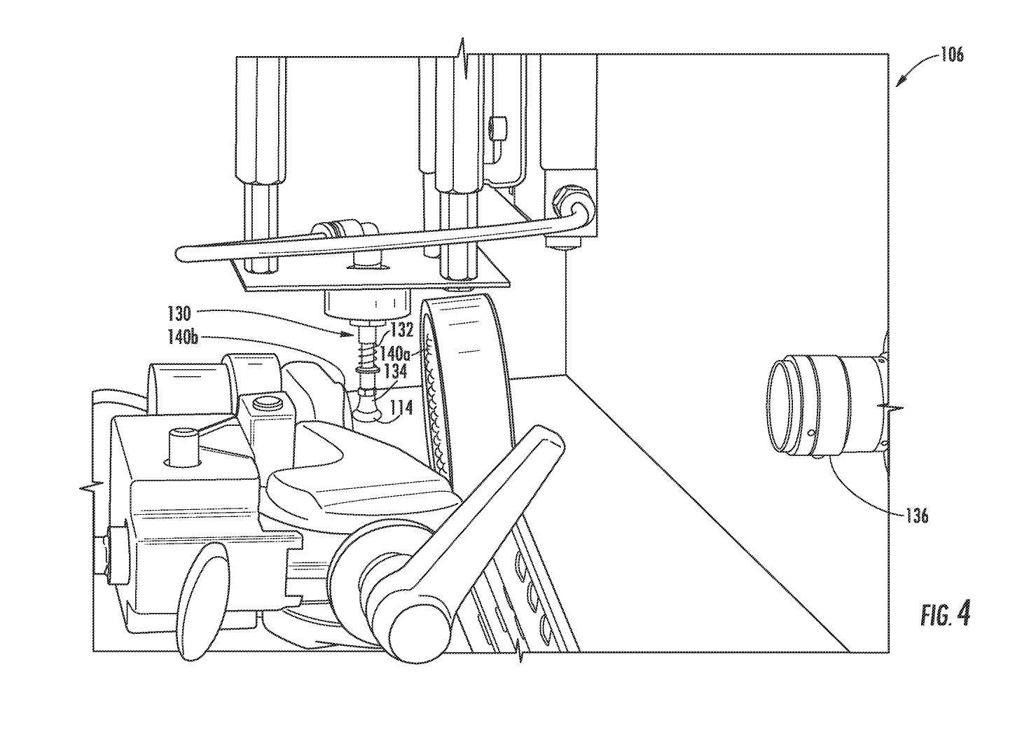

Once the soybean seed 114 has been oriented on the minor axis 118, such as by vibrating the soybean seed 114 with the vibratory device 102, a known feature of the soybean seed may then be identified in order to ensure that the proper orientation was achieved and further orient the soybean seed. In some embodiments the identification process may occur at the vibratory device 102. However, as illustrated in FIG. 4, the apparatus 100 may alternatively use the robotic arm 104 to pick up the soybean seed 114 and transfer the soybean seed to the machine vision device 106 at a different location. Although the robotic arm 104 (or other transfer assembly) may include various embodiments of features which enable transfer of the soybean seed 114, the illustrated robotic arm includes a suction device 130 which allows the robotic arm to grasp the soybean seed. The suction device 130 is spring-loaded in the illustrated embodiment, through use of a spring 132 which allows the robotic arm 104 to securely contact a suction tip 134 to the soybean seed 114 when picking the soybean seed up without placing excessive force on the soybean seed, which could potentially damage the soybean seed. Thereby, the robotic arm 104 may transfer the soybean seed 114 to the machine vision device 106.

The machine vision device 106 may include a camera 136 which is configured to identify a location of a known feature of the soybean seed 114. For example, the machine vision device 106 may use the camera 136 to identify a know shape, such as the shape of the hilum 120, the embryo 122, or the perimeter 138 of the soybean seed 114 (see FIG. 3). Alternatively or additionally, the camera 136 may be used to identify a known color, such as the color of the hilum 120 or the embryo 122, which may be darker than the remaining portions of the soybean seed 114. In order to assist in identifying known features of the soybean seed 114, the machine vision device 106 may further include one or more lights 140a, 140b which may illuminate the soybean seed to thereby improve contrast. A first light 140a may illuminate the front side of the soybean seed 114 facing the camera 136, whereas a second light 140b may backlight the back side of the soybean seed. Backlighting the soybean seed 114 may be useful for identifying the perimeter 138 of the soybean seed and/or the embryo 122, which may be recessed from the surface of the soybean seed.

Further, in some embodiments the robotic arm 104 may be configured to rotate the soybean seed 114. For example, when the soybean seed 114 is oriented on the minor axis 118 as described above, and the suction device 130 may rotate the soybean seed about the minor axis when the soybean seed is grasped from above by the robotic arm 104, as illustrated. Accordingly, the robotic arm 104 may rotate the soybean seed 114 such that the camera 136 can view all sides of the outside surface of the soybean seed. Thus, for example, the camera 136 may identify the location of the hilum 120, the embryo 122, and/or the perimeter 138 of the soybean seed 114.

Once the location of a known feature of the soybean seed 114 is identified, the soybean seed may be transferred to the cutting device. For example, as illustrated in FIG. 5, the soybean seed 114 may be transferred by the robotic arm 104 to the laser 108. The laser 108 may cut the soybean seed 114 to thereby remove a sample portion 114a of the soybean seed. Using the information regarding the location of a known feature of the soybean seed 114, as determined using the machine vision device 106, the robotic arm 104 may position the soybean seed so as to avoid cutting the embryo 122. Thus, for example, the robotic arm 104 may rotate the soybean seed 114 such that the hilum 120 and/or the embryo 122 are substantially opposite the portion of the soybean seed which is cut.

In some embodiments the laser 108 may move during the cutting operation, whereas in other embodiments the robotic arm may move the soybean seed 114 through a path whereby a laser beam 108a produced by the laser 108 is incident with the soybean seed. Further, the relative motion of the soybean seed 114 to the laser beam 108a may be controlled to obtain the desired size and shape of the sample portion 114a of the soybean seed. For example, in some embodiments the laser beam 108a may cut along an arc to thereby produce a sample portion 114a which is substantially crescent-shaped. Cutting along an arc may be useful to ensure that the embryo 122 of the soybean seed 114 is not damaged during the cutting operation, as this motion may provide for a larger separation between the laser beam 108a and the embryo. Further, by using the information regarding the perimeter 138 of the soybean seed 114, the laser beam 108a may be used to cut a sample portion 114a of a desired sample size.

As further illustrated, the sample portion 114a may be deposited in a first compartment 110a in the first container 110, which may comprise a megatiter plate with an array of compartments. A funnel 142 may be used to direct the sample portion 114a to the first compartment 110a. In some embodiments the first container 110 may be moveable relative to the funnel 142 such that when the sample portion 114a falls through the funnel 142, it lands in the desired compartment therein.

A remaining portion 114b of the soybean seed 114 may be transported by the robotic arm 104 to a second compartment 112a in the second container 112, which may comprise a blister package with an array of compartments, or other container configured for planting seeds. The second compartment 112a in the second container 112 may correspond with the first compartment 110a in the first container 110 such that it may be possible to know which sample portion came from which seed. Thereby, for example, the remaining portion 114b of the soybean seed 114 may be stored for future planting and the sample portion 114a of the soybean seed may be tested for various characteristics. Thus, since the soybean seed 114 may still comprise an undamaged embryo 122, the remaining portion 114b may be planted to determine growth characteristics and/or produce additional seeds. By way of further example, DNA or proteins may be extracted from the sample portion 114a of the soybean seed 114 through various procedures. For instance, a cell lysis solution may be added to the sample portion 114a of the soybean seed 114 to break down the sample portion and separate the DNA and proteins. Thereafter, through centrifuge, decanting, or other methods the DNA may be separated from the proteins. Thereby analysis of the soybean seed 114 may be conducted without harming viability of the soybean seed.

In other embodiments, the soybean seed 114 may be subjected to an alternate or additional non-destructive testing procedure. For example, in some embodiments the soybean seed 114 may be subjected to a non-destructive testing procedure proximate the sample location using a spectrometer, a near infrared (NIR) spectrometer, a nuclear magnetic resonance (MNR) spectrometer, a hardness testing device, or any combination of the above.

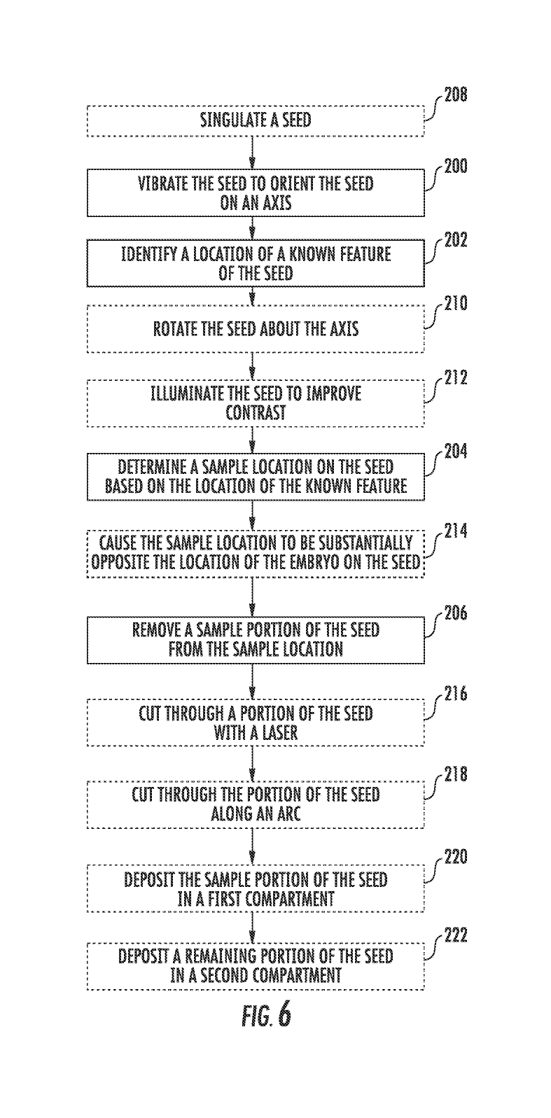

In further embodiments methods of non-destructive sampling of a seed are provided. For example, one method of non-destructive sampling of a seed is illustrated in FIG. 6. The method may comprise vibrating the seed to orient the seed on an axis at operation 200. For example, the soybean seed 114 may be oriented on its minor axis 118 using the vibratory device 102. The method may further include identifying a location of a known feature of the seed at operation 202. As described above, examples of known features include the hilum 120, embryo 122, or other features such as known shapes (for example the perimeter 138) or known colors which may be identified using the machine vision device 106. Further, the method may comprise determining a sample location on the seed based on the location of the known feature at operation 204. Thereby, the method may further include removing a sample portion of the seed from the sample location at operation 206. For example, the seed may be cut using the laser 108.

In some embodiments the method may additionally or alternatively comprise other operations including those operations illustrated in dashed lines in FIG. 6. For example, the method may include singulating the seed at operation 208 prior to vibrating the seed at operation 200. Further, identifying a location of the known feature of the seed at operation 202 may comprise rotating the seed about the axis at operation 210. For example, the suction device 130 of the robotic arm 104 may be configured to rotate in some embodiments. Additionally, identifying the location of the known feature at operation 202 may comprise illuminating the seed to improve contrast at operation 212. For example, a seed may be illuminated using the lights 140a, 140b.

Also, determining the sample location at operation 204 may comprise causing the sample location to be substantially opposite the location of the embryo on the seed at operation 214. Accordingly, the operation 206 of removing a sample portion of the seed from the sample location may not damage the embryo. In some embodiments removing a sample portion of the seed at operation 206 may comprise cutting through a portion of the seed with a laser at operation 216. For example, the seed may be cut using the laser 108. Further, cutting through a portion of the seed at operation 216 may comprise cutting through the portion of the seed along an arc at operation 218. The method may also comprise depositing the sample portion of the seed in a first compartment at operation 220. For example, the sample portion 114a of a seed may be deposited in the first compartment 110a of the first container 110. Further, the method may include depositing a remaining portion of the seed in a second compartment at operation 222. For example, the remaining portion 114b may be deposited in the second compartment 112a of the second container 112, wherein the second compartment corresponds with the first compartment. In some embodiments of the method, the remaining portion of the seed may comprise an embryo such that the remaining portion of the seed may be planted.

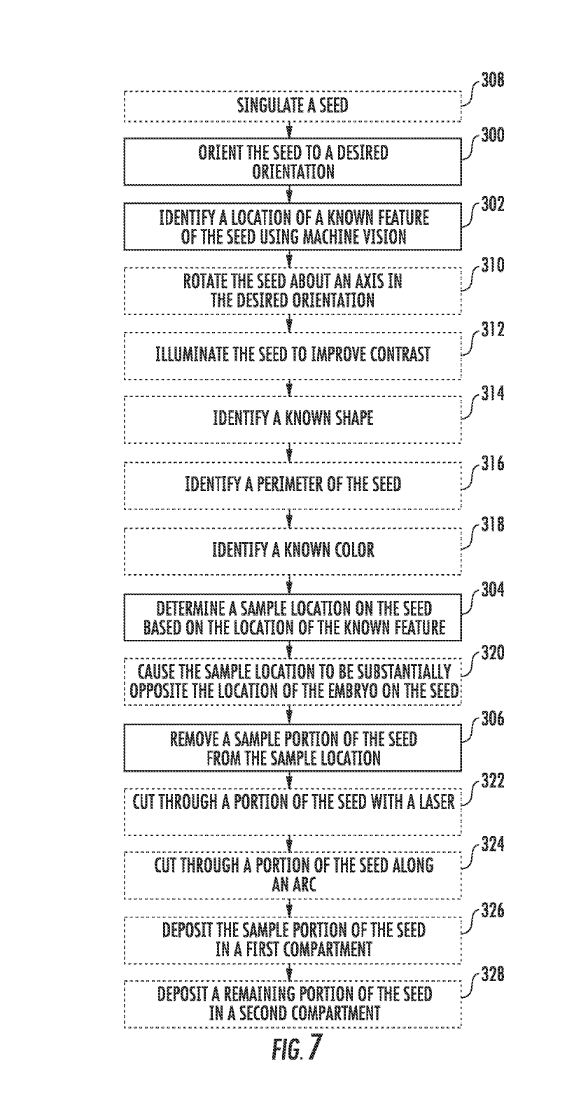

Additional methods of non-destructive sampling of a seed are illustrated in FIG. 7. A method may comprise orienting a seed to a desired orientation at operation 300. For example, the vibratory device 102 may be used to orient a seed to the desired axis 128, although other methods of orienting the seed may not involve the vibratory device, as discussed above. The method may additionally include identifying a location of a known feature of the seed using machine vision at operation 302. As described above, examples of known features include the hilum 120, embryo 122, or other features such as known shapes (for example the perimeter 138) or known colors which may be identified using the machine vision device 106. Further, the method may include determining a sample location on the seed based on the location of the known feature at operation 304. Thereafter the method may comprise removing a sample portion of the seed from the sample location at operation 306. For example, the sample portion 114a of the soybean seed 114 may be removed using the laser 108.

In some embodiments the method may additionally or alternatively comprise other operations including those operations illustrated in dashed lines in FIG. 7. For example, the method may include singulating a seed at operation 308 prior to orienting the seed at operation 300. Additionally, identifying the location of the known feature at operation 302 may comprise rotating the seed about an axis in the desired orientation at operation 310 and/or illuminating the seed to improve contrast at operation 312. For example, the seed may be rotated by the suction device 130 of the robotic arm 104 and illuminated by the lights 140a, 140b. Further, identifying the location of the known feature at operation 302 may comprise identifying a known shape at operation 314, which may include identifying a perimeter of the seed at operation 316, or the known feature may in some embodiments comprise a hilum or an embryo. Also, identifying a location of a known feature of the seed using machine vision at operation 302 may comprise identifying a known color at operation 318.

In further embodiments of the method the operation 304 of determining the sample location may comprise causing the sample location to be substantially opposite the location of the embryo on the seed at operation 320. This operation may be conducted, for example, when the known feature comprises the embryo, and may involve rotating the seed using the suction device 130. Additionally, removing the sample portion of the seed from the sample location at operation 306 may comprise cutting through a portion of the seed with a laser at operation 322. For example, the laser 108 may be used to cut the soybean seed 114. Further, cutting through a portion of the seed with a laser at operation 322 may comprise cutting through a portion of the seed along an arc at operation 324. Thereby further measures for avoiding damaging the embryo of the seed are provided. Also, the method may include depositing the sample portion of the seed in a first compartment at operation 326 and depositing a remainder portion of the seed in a second compartment at operation 328. For example, in the illustrated embodiment the sample portion 114a of the soybean seed 114 may be deposited in the first compartment 110a of the first container 110, and the remaining portion 114b of the soybean seed may be deposited in the second compartment 112a of the second container 112. Thereby the second compartment 112a may correspond to the first compartment 110a so that it may be possible, for example, to conduct analyses on the sample portion 114a of the soybean seed 114 and plant the remaining portion 114b of the soybean seed while keeping track of both as being related to one another.

In still other embodiments of the methods and apparatuses described herein, the soybean seed 114 may be subjected to an alternate or additional non-destructive testing procedure. For example, in some embodiments the soybean seed 114 may be subjected to a non-destructive testing procedure proximate the sample location using a spectrometer, a near infrared (NIR) spectrometer, a nuclear magnetic resonance (MNR) spectrometer, a hardness testing device, a hyperspectral imaging device, a UV imaging device, and X-Ray device, and RGB imaging system, or any combination of the above.

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of non-destructive sampling of a seed, comprising:
vibrating the seed to orient the seed on an axis;
identifying a location of a known feature of the seed;
determining a sample location on the seed based on the location of the known feature; and
performing a non-destructive testing procedure on the seed proximate the sample location.

2. The method of claim 1, wherein the known feature comprises an embryo.

3. The method of claim 2, wherein determining the sample location comprises causing the sample location to be substantially opposite the location of the embryo on the seed.

4. The method of claim 1, wherein the known feature comprises a hilum.

5. The method of claim 1, wherein identifying the location of the known feature comprises rotating the seed about the axis.

6. The method of claim 1, wherein identifying the location of the known feature on the seed comprises illuminating the seed to improve contrast.

7. The method of claim 1, wherein identifying the location of the known feature comprises identifying a known shape.

8. The method of claim 7, wherein identifying a known shape comprises identifying a perimeter of the seed.

9. The method of claim 1, wherein identifying the location of the known feature comprises identifying a known color.

10. The method of claim 1, further comprising singulating the seed prior to vibrating the seed.

11. The method of claim 1, wherein performing the non-destructive testing procedure comprises removing a sample portion of the seed from the sample location.

12. The method of claim 11, wherein removing the sample portion of the seed comprises cutting through a portion of the seed with a laser.

13. The method of claim 12, wherein cutting through the portion of the seed with the laser comprises cutting through a portion of the seed along an arc.

14. The method of claim 11, further comprising depositing the sample portion of the seed in a first compartment; and
depositing a remaining portion of the seed in a second compartment,
wherein the second compartment corresponds with the first compartment.

15. The method of claim 14, wherein the remaining portion of the seed comprises an embryo.

16. The method of claim 1, wherein the non-destructive testing procedure comprises a testing procedure selected from the group consisting of:
spectroscopy;
near infrared (NIR) spectroscopy;
nuclear magnetic resonance (NMR) spectroscopy;
hardness testing;
Hyperspectral measurements and imaging;
X-ray imaging;
UV measurements and imaging;
RGB measurements and imaging; and
combinations thereof.

17. A method of non-destructive sampling of a seed, comprising:
orienting the seed to a desired orientation;
identifying a location of a known feature of the seed using machine vision;
determining a sample location on the seed based on the location of the known feature; and
performing a non-destructive testing procedure on the seed proximate the sample location.

18. The method of claim 17, wherein the known feature comprises an embryo.

19. The method of claim 18, wherein determining the sample location comprises causing the sample location to be substantially opposite the location of the embryo on the seed.

20. The method of claim 17, wherein the known feature comprises a hilum.

21. The method of claim 17, wherein identifying the location of the known feature comprises rotating the seed about an axis in the desired orientation.

22. The method of claim 17, wherein identifying the location of the known feature on the seed comprises illuminating the seed to improve contrast.

23. The method of claim 17, wherein identifying the location of the known feature comprises identifying a known shape.

24. The method of claim 23, wherein identifying a known shape comprises identifying a perimeter of the seed.

25. The method of claim 17, wherein identifying the location of the known feature comprises identifying a known color.

26. The method of claim 17, further comprising singulating the seed prior to orienting the seed.

27. The method of claim 17, wherein performing the non-destructive testing procedure comprises removing a sample portion of the seed from the sample location.

28. The method of claim 27, wherein removing the sample portion of the seed comprises cutting through a portion of the seed with a laser.

29. The method of claim 28, wherein cutting through a portion of the seed with the laser comprises cutting through a portion of the seed along an arc.

30. The method of claim 27, further comprising depositing the sample portion of the seed in a first compartment; and
depositing a remaining portion of the seed in a second compartment,
wherein the second compartment corresponds with the first compartment.

31. The method of claim 30, wherein the remaining portion of the seed comprises an embryo.

32. The method of claim 17, wherein the non-destructive testing procedure comprises a testing procedure selected from the group consisting of:
spectroscopy;
near infrared (NIR) spectroscopy;
nuclear magnetic resonance (NMR) spectroscopy;
hardness testing;
Hyperspectral measurements and imaging;
X-ray imaging;
UV measurements and imaging;
RGB measurements and imaging; and
combinations thereof.

33. An apparatus configured to remove a sample portion of a seed, comprising:
a vibratory device configured to vibrate the seed and orient the seed on an axis;
a camera configured to identify a location of a known feature of the seed; and
a testing device configured to perform a non-destructive testing procedure on the seed.

34. The apparatus of claim 33, further comprising a singulator configured to singulate the seed.

35. The apparatus of claim 33, wherein the vibratory device comprises a sloped surface configured to center the seed such that the axis is coaxial with a desired axis.

36. The apparatus of claim 33, wherein the testing device comprises a cutting device configured to cut the seed to thereby remove a sample portion of the seed

37. The apparatus of claim 36, wherein the cutting device comprises a laser.

38. The apparatus of claim 33, further comprising a suction device configured to contact the seed and rotate the seed about the axis.

39. The apparatus of claim 38, wherein the suction device is spring-loaded.

40. The apparatus of claim 33, further comprising a light configured to illuminate the seed to improve contrast.

41. The apparatus of claim 33, wherein the testing device comprises a device selected from the group consisting of:
a spectrometer;
a near infrared (NIR) spectrometer;
nuclear magnetic resonance (NMR) spectrometer
hardness testing;
Hyperspectral measurements and imaging;
X-ray imaging;
UV measurements and imaging;
RGB measurements and imaging; and
combinations thereof.
